(19) United States
(12) Patent Application Publication
(10) Pub. No.: US 2024/0120552 A1
(43) Pub. Date: Apr. 11, 2024

(54) Sulfide Solid-State Battery, Printed Circuit Board with Sulfide Solid-State Battery, and Manufacturing Method of Sulfide Solid-State Battery

(71) Applicant: TOYOTA JIDOSHA KABUSHIKI KAISHA, Toyota-shi Aichi-ken (JP)

(72) Inventors: Shinji NAKANISHI, Royota-shi Aichi-ken (JP); Takuya MATSUYAMA, Susono-shi Shizuoka-ken (JP)

(73) Assignee: TOYOTA JIDOSHA KABUSHIKI KAISHA, Toyota-shi Aichi-ken (JP)

(21) Appl. No.: 18/219,198

(22) Filed: Jul. 7, 2023

(30) Foreign Application Priority Data
Sep. 16, 2022 (JP) 2022-148515

(51) Int. Cl. H01M 10/0585; H01M 10/0562; H05K 3/34

(52) U.S. Cl. CPC H01M 10/0585; H01M 10/0562; H05K 3/34; H01M 2300/0068; H01M 2300/0094; H05K 2201/10037; H05K 2203/043

(57) ABSTRACT

The sulfide solid-state battery of the present disclosure has a battery laminate having one or more unit batteries; and an inorganic coating layer covering at least a portion of the periphery of the battery laminate. The unit battery is formed by laminating a positive electrode layer, a solid electrolyte layer, and a negative electrode layer in this order. At least one of the positive electrode layer, the solid electrolyte layer, and the negative electrode layer contains a sulfide solid electrolyte. The inorganic coating layer is made of an inorganic glass having a glass transition point of 260° C. or higher and 360° C. or lower.

### CROSS-REFERENCE TO RELATED APPLICATION

This application claims priority to Japanese Patent Application No. 2022-148515 filed on Sep. 16, 2022 incorporated herein by reference in its entirety.

### BACKGROUND

### 1. Technical Field

The present disclosure relates to a sulfide solid-state battery, a printed circuit board with a sulfide solid-state battery, and a manufacturing method of a sulfide solid-state battery.

### 2. Description of Related Art

In recent years, various techniques for sealing a battery using a resin have been disclosed (Japanese Unexamined Patent Application Publication No. 2017-220447 (JP 2017-220447 A), Japanese Unexamined Patent Application Publication No. 2018-116917 (JP 2018-116917 A), and Japanese Unexamined Patent Application Publication No. 2020-021551 (JP 2020-021551 A)).

For example, JP 2020-021551 A discloses a battery laminate including two or more unit batteries; and a sulfide solid-state battery including a resin layer covering a side surface of the battery laminate. The unit battery is configured of a positive electrode current collector layer, a positive electrode active material layer, a solid electrolyte layer, a negative electrode active material layer, and a negative electrode current collector layer laminated in this order. At least one of the positive electrode current collector layer, the positive electrode active material layer, the solid electrolyte layer, the negative electrode active material layer, and the negative electrode current collector layer includes an extension portion extending outward from the other layer on the side surface of the battery laminate. In addition, a gap is provided between the extending portions. The ratio of the compressive elastic modulus of the resin layer to the compressive elastic modulus of the battery laminate is 0.4 or less.

### SUMMARY

Depending on an application of the battery, conventional sealing using a general resin may have insufficient performance such as barrier property and heat resistance.

On the other hand, the present disclosure provides a novel sulfide solid-state battery sealed with an inorganic material.

Also, in some embodiments, depending on the application of the battery, there may be a case where the battery is mounted on a printed circuit board using a soldering process, particularly a reflow soldering process.

However, in general, it is considered that a sulfide solid-state battery using a sulfide solid electrolyte is not suitable for mounting on a printed circuit board using a soldering process because the sulfide solid electrolyte is vulnerable to heat. In particular, as in the above-described prior art, it is considered that a sulfide solid-state battery sealed with a general resin is not particularly suitable for mounting on a printed circuit board using a soldering process because a general resin is vulnerable to heat.

On the other hand, the present disclosure provides a sulfide solid-state battery that can be mounted on a printed circuit board using a soldering process, particularly a reflow soldering process.

The present inventors have found that the above issue can be solved by the following aspects, and have completed the present disclosure. That is, the present disclosure is as follows.

### First Aspect

A sulfide solid-state battery includes: a battery laminate including one or more unit batteries, the unit battery configured of a positive electrode layer, a solid electrolyte layer, and a negative electrode layer laminated in this order; and an inorganic coating layer coating at least a portion of a periphery of the battery laminate.

At least one of the positive electrode layer, the solid electrolyte layer, and the negative electrode layer contains a sulfide solid electrolyte, and the inorganic coating layer is made of an inorganic glass of which a glass transition point is 260° C. or higher and 360° C. or lower.

### Second Aspect

In the sulfide solid-state battery according to the first aspect, the inorganic coating layer is coated with a resin coating layer made of a fluorine-based resin.

### Third Aspect

A printed circuit board with a sulfide solid-state battery includes: a printed circuit board; and the sulfide solid-state battery according to the first aspect, the sulfide solid-state battery being soldered to the printed circuit board.

### Fourth Aspect

A manufacturing method of the printed circuit board with the sulfide solid-state battery according to the third aspect includes soldering the sulfide solid-state battery to the printed circuit board by reflow soldering.

### Fifth Aspect

A manufacturing method of the sulfide solid-state battery according to any one of the first to third aspects includes:
(a) preparing the battery laminate; and
(b) forming the inorganic coating layer on at least a portion of the periphery of the battery laminate.

The present disclosure provides a novel sulfide solid-state battery sealed with an inorganic material and a manufacturing method thereof. In particular, the present disclosure provides a sulfide solid-state battery that can be mounted on a printed circuit board using a soldering process, particularly a reflow soldering process, and a manufacturing method thereof.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1A is a cross-sectional view illustrating an example of a sulfide solid-state battery according to an embodiment of the present disclosure.

FIG. 1B is a cross-sectional view illustrating an example of a sulfide solid-state battery according to an embodiment of the present disclosure.

FIG. 1C is a cross-sectional view of an example of a sulfide solid-state battery according to an embodiment of the present disclosure.

FIG. 2A is a cross-sectional view illustrating another exemplary sulfide solid-state battery according to the present disclosure;

FIG. 2B is a cross-sectional view illustrating another exemplary sulfide solid-state battery according to the present disclosure;

FIG. 2C is a top view illustrating another exemplary sulfide solid-state battery of the present disclosure;

FIG. 3 is a graph showing the evaluation results of the water vapor permeability of the inorganic coating layer of Example 1 and the laminate of the inorganic coating layer and the resin coating layer of Example 2;

FIG. 4A is a cross-sectional view showing the sulfide solid-state batteries of Examples 3 and 4;

FIG. 4B is a cross-sectional view showing the sulfide solid-state batteries of Examples 3 and 4;

FIG. 4C is a top view of the sulfide solid-state batteries of Examples 3 and 4; and

FIG. 5 is a graph showing the relationship between the number of cycles and the charge/discharge efficiency for the sulfide solid-state batteries of Examples 3 and 4.

### DETAILED DESCRIPTION OF EMBODIMENTS

Hereinafter, embodiments of the present disclosure will be described in detail with reference to the drawings. However, the embodiments shown in the drawings are examples of the present disclosure, and do not limit the present disclosure.

### Sulfide Solid-State Battery

The sulfide solid-state battery of the present disclosure has a battery laminate having one or more unit batteries; and an inorganic coating layer covering at least a portion of the periphery of the battery laminate. Further, in the sulfide solid-state battery of the present disclosure, the unit battery is formed by laminating a positive electrode layer, a solid electrolyte layer, and a negative electrode layer in this order. At least one of the positive electrode layer, the solid electrolyte layer, and the negative electrode layer contains a sulfide solid electrolyte. The inorganic coating layer is composed of an inorganic glass having a glass transition point of 260° C. or higher and 360° C. or lower.

In the context of the present disclosure, the “glass transition point” can be evaluated according to JISK0129:2005 by differential thermal analysis (DTA) measurements. Specifically, for example, in the differential curve of DTA curve obtained by using α-alumina as a reference, the temperature of the central portion of the first endothermic peak (the intersection of the tangent at the first inflection point and the second inflection point) can be set as the glass transition point (Tg).

Further, in the context of the present disclosure, the “periphery of the battery laminate” indicates both surfaces of each layer of the battery laminate in the stacking direction, and the peripheral edge of each layer of the battery laminate in the plane direction. Therefore, in the sulfide solid-state battery of the present disclosure, the inorganic coating layer covers at least a part of both surfaces of each layer of the battery laminate in the stacking direction and a peripheral edge of each layer of the battery laminate in the plane direction. For example, the inorganic coating layer may cover one or both of both surfaces in the stacking direction of each layer of the battery laminate, or may cover all or a part of the peripheral edge in the surface direction of each layer of the battery laminate. In addition, for example, the inorganic coating layer may cover one or both of both surfaces of each layer of the battery laminate in the stacking direction, and all or a part of the peripheral edge of each layer of the battery laminate in the plane direction.

The inventors of the present disclosure have found that an inorganic glass having a suitable glass transition point can cover at least a part of the periphery of a sulfide solid-state battery without significantly deteriorating the sulfide solid electrolyte, and have conceived the sulfide solid-state battery of the present disclosure. In this regard, the inventors of the present disclosure have conducted heat treatment of a positive electrode active material layer comprising a lithium niobate-cobalt-manganese based positive electrode active material coated with lithium niobate and a Li₂S—P₂S₅ based solid electrolyte, and as a result, it was confirmed that the ion conductivity of the solid electrolyte dropped from around 300° C. or more, but if it is 360° C. or less, ion conductivity is maintained.

In the present disclosure, the inorganic coating layer covers at least a part of the periphery of the battery laminate. Thus, the sulfide solid-state battery of the present disclosure may not have an exterior body such as a laminate film or a metal can. Therefore, the sulfide solid-state battery of the present disclosure is made more compact than conventional sulfide solid-state batteries that require an exterior body such as an aluminum laminate film, thereby improving the energy density of the battery. However, the sulfide solid-state battery of the present disclosure may further include an exterior body such as an aluminum laminate film in addition to the inorganic coating layer and the optional resin coating layer.

Further, the disclosures of the present disclosure have found that soldering can be performed without remarkably deteriorating the sulfide solid electrolyte in a soldering process from a low temperature to an intermediate temperature, and that, if an inorganic glass having an appropriate glass transition point is used, at least a part of the periphery of the sulfide solid-state battery can be covered without remarkably deteriorating the sulfide solid electrolyte and can withstand the heat of the soldering process. In addition, the inventors of the present disclosure have conceived the sulfide solid-state battery of the present disclosure. The sulfide solid-state battery of the present disclosure can unexpectedly be mounted on a printed circuit board using a soldering process, particularly a reflow soldering process.

In the context of the present disclosure, a “reflow soldering step” means a step of soldering a solder previously applied at a normal temperature by subsequent heating.

In the “reflow soldering process”, a paste-like or cream-like solder is applied or printed to a necessary portion of a printed circuit board. The object to be soldered is then placed in place on the printed circuit board. Finally, the soldering objects per printed circuit board are passed through a hot reflow furnace to melt the solder. Then, the object to be soldered and the printed circuit board are soldered. Here, examples of the heating method in the reflow furnace include an infrared method and a hot air method.

Note that, with respect to the “reflow soldering step” as described above, the step of soldering the solder melted by heat is caused to flow between the object to be soldered and the printed circuit board is sometimes referred to as a “flow soldering step”. The sulfide solid-state battery of the present disclosure can naturally be mounted on a printed circuit board by not only a “reflow soldering step” but also a “flow soldering step”.

### Inorganic Coating Layer

The inorganic coating layer of the sulfide solid-state battery of the present disclosure is composed of an inorganic glass having a glass transition point of 260° C. or higher and 360° C. or lower. Here, the glass transition point may be 270° C. or higher, 280° C. or higher, 290° C. or higher, 300° C. or higher, 310° C. or higher, 320° C. or higher, 330° C. or higher, 340° C. or higher, or 350° C. or higher. The glass transition point may be 350° C. or less, 340° C. or less, 330° C. or less, 320° C. or less, 310° C. or less, 300° C. or less, 290° C. or less, 280° C. or less, or 270° C. or less.

Examples of the inorganic glass having a relatively low glass transition point include silicate-based glass, borate-based glass, bismuth silicate-based glass, borosilicate-based glass, vanadium oxide-based glass, and phosphate-based glass.

Some silicate-based glasses include, for example, SiO₂—ZnO, SiO₂—Li₂O, SiO₂—Na₂O, SiO₂—CaO, SiO₂—MgO, SiO₂—Al₂O₃, and the like as main components. Some bismuth silicate-based glasses contain SiO₂—Bi₂O₃—ZnO, SiO₂—Bi₂O₃—Li₂O, SiO₂—Bi₂O₃—Na₂O, SiO₂—Bi₂O₃—CaO, and the like as main components. Some borate-based glasses contain, for example, B₂O₃—ZnO, B₂O₃—Li₂O, B₂O₃—Na₂O, B₂O₃—CaO, B₂O₃—MgO, B₂O₃—Al₂O₃, and the like as main components. The borosilicate-based glasses include, for example, SiO₂—B₂O₃—ZnO, SiO₂—B₂O₃—Li₂O, SiO₂—B₂O₃—Na₂O, SiO₂—B₂O₃—CaO, and the like as main components. The vanadium oxide-based glass includes, for example, V₂O₅—B₂O₃, V₂O₅—B₂O₃—SiO₂, V₂O₅—P₂O₅, V₂O₅—B₂O₃—P₂O₅, and the like as main components. Phosphoric acid-based glasses include, for example, P₂O₅—Li₂O, P₂O₅—Na₂O, P₂O₅—CaO, P₂O₅—MgO, P₂O₅—Al₂O₃, and the like as main components.

In addition to the above-described components, the low glass transition point glass may contain one or more of SiO₂, ZnO, Na₂O, B₂O₃, Li₂O, SnO, BaO, CaO, Al₂O₃, and the like as appropriate. Here, the “main component” means that the component is more than 50 mass %, 60 mass % or more, 70 mass % or more, 80 mass % or more, or 90 mass % or more of the weight of the inorganic glass.

The inorganic coating layer may optionally contain fillers, in particular inorganic fillers. Such inorganic fillers include, for example, an oxide (alumina (Al₂O₃), silica (SiO₂), titania (TiO₂), zirconia (ZrO₂), and others CeO₂, Y₂O₃, La₂O₃, LiAlO₂, Li₂O, BeO, B₂O₃, Na₂O, MgO, P₂O₅, CaO, Cr₂O₃, Fe₂O₃, ZnO, etc.), porous composite ceramics (zeolite, sepiolite, parigolskite, etc.), nitrides (Si₃N₄, BN, AlN, TiN, Ba₃N₂, etc.), carbides (SiC, ZrC, B₄C), carbonates (MgCO₃, CaCO₃, etc.), or sulfates (CaSO₄, BaSO₄, etc.) can be used. However, the inorganic filler is not limited thereto.

The material used for these inorganic fillers may be a single material or a mixture of two or more materials. The shape of the inorganic filler is not particularly limited. The shape of the inorganic filler may be a spherical shape, an elliptical shape, a fiber shape, a scaly shape, or the like.

The method of forming the inorganic coating layer is not particularly limited. For example, by a method such as a capillary underfill method, an injection molding method, a transfer molding method, or a dipping molding method, a material of an inorganic coating layer softened or liquefied by heating is supplied to the periphery of the battery laminate, and the material is cooled and cured to form an inorganic coating layer on a side surface of the battery laminate. Further, it is also possible to obtain an inorganic coating layer by forming a sheet of the inorganic coating layer in advance, sandwiching the battery laminate with the sheet, and softening the sheet by being heated together with the battery laminate.

### Resin Coating Layer

In the sulfide solid-state battery of the present disclosure, the inorganic coating layer may be coated with a resin coating layer made of a fluorine-based resin.

In the case where the inorganic coating layer is coated with a resin coating layer made of a fluorine-based resin as described above, the fluorine-based resin has a relatively high gas barrier property, so that it is possible to better suppress the surrounding gas from reaching the battery laminate through the coating layer. The proportion of the fluorine-based resin in the resin coating layer may be more than 50% by mass, 60% by mass or more, 70% by mass or more, 80% by mass or more, or 90% by mass or more.

Such a fluorine-based resin may be any resin having a fluorine atom (F) in the structural unit (repeating unit). In particular, such a fluorine-based resin may have a glass transition point of 260° C. or higher and 360° C. or lower. Here, the glass transition point may be 270° C. or higher, 280° C. or higher, 290° C. or higher, 300° C. or higher, 310° C. or higher, 320° C. or higher, 330° C. or higher, 340° C. or higher, or 350° C. or higher. The glass transition point may be 350° C. or less, 340° C. or less, 330° C. or less, 320° C. or less, 310° C. or less, 300° C. or less, 290° C. or less, 280° C. or less, or 270° C. or less.

Such fluororesins may be, for example, polyvinylidene fluoride (PVdF), polytetrafluoroethylene (PTFE), vinylidene fluoride-hexafluoropropylene copolymer (PVdF-HFP), fluoropolyether (FPE), perfluoropolyether (PFPE), perfluoroalkoxyalkane (PFA), perfluoroethylene propene copolymer (FEP), ethylene-tetrafluoroethylene copolymer (ETFE), polychlorotrifluoroethylene (PCTFE), ethylene chlorotrifluoroethylene copolymer (ECTFE), tetrafluoroethylene-perfluorodioxole copolymer (TFE/PDD), polyvinyl fluoride (PVF), and the like.

The resin coating layer may optionally contain a filler, in particular an inorganic filler. For such inorganic fillers, reference can be made to the description in the inorganic coating layer.

The resin coating layer can be obtained by any method. For example, for the method of forming the resin coating layer, reference can be made to the description of JP 2017-220447 A, JP 2018-116917 A, and JP 2020-021551 A, and the above description of the inorganic coating layer.

### Type of Sulfide Solid-State Battery

In the present disclosure, sulfide solid-state batteries may include solid state lithium ion batteries, solid sodium ion batteries, solid state magnesium ion batteries, and solid state calcium ion batteries, and the like. In some embodiments, the sulfide solid-state battery includes a solid sodium ion battery. In some embodiments, the sulfide solid-state battery includes a solid-state lithium-ion battery.

The sulfide solid-state battery of the present disclosure may be a primary battery or a secondary battery. In some embodiments, the sulfide solid-state battery is a secondary battery. This is because the secondary battery can be repeatedly charged and discharged, and is useful, for example, as an in-vehicle battery. Therefore, in some embodiments, the sulfide solid-state battery of the present disclosure is a solid lithium ion secondary battery.

### Laminated Structure of Battery Laminate

In the present disclosure, the battery laminate has one or more unit batteries, in particular two or more unit batteries. In this unit battery, a positive electrode layer, a solid electrolyte layer, and a negative electrode layer are stacked in this order. The positive electrode layer may include a positive electrode current collector layer and a positive electrode active material layer. The negative electrode layer may include a negative electrode active material layer and a negative electrode current collector layer.

In the present disclosure, the battery laminate may be a monopolar battery laminate or a bipolar battery laminate.

### Monopolar Battery Laminate

When the battery laminate is a monopolar battery laminate, the two unit batteries adjacent to each other in the stacking direction may have a monopolar configuration sharing the positive electrode current collector layer or the negative electrode current collector layer.

Thus, for example, the battery laminate may be a stack of two unit batteries sharing a negative electrode current collector layer. Specifically, the battery laminate may include a positive electrode current collector layer, a positive electrode active material layer, a solid electrolyte layer, a negative electrode active material layer, a negative electrode current collector layer, a negative electrode active material layer, a solid electrolyte layer, a positive electrode active material layer, and a positive electrode current collector layer in this order (not shown).

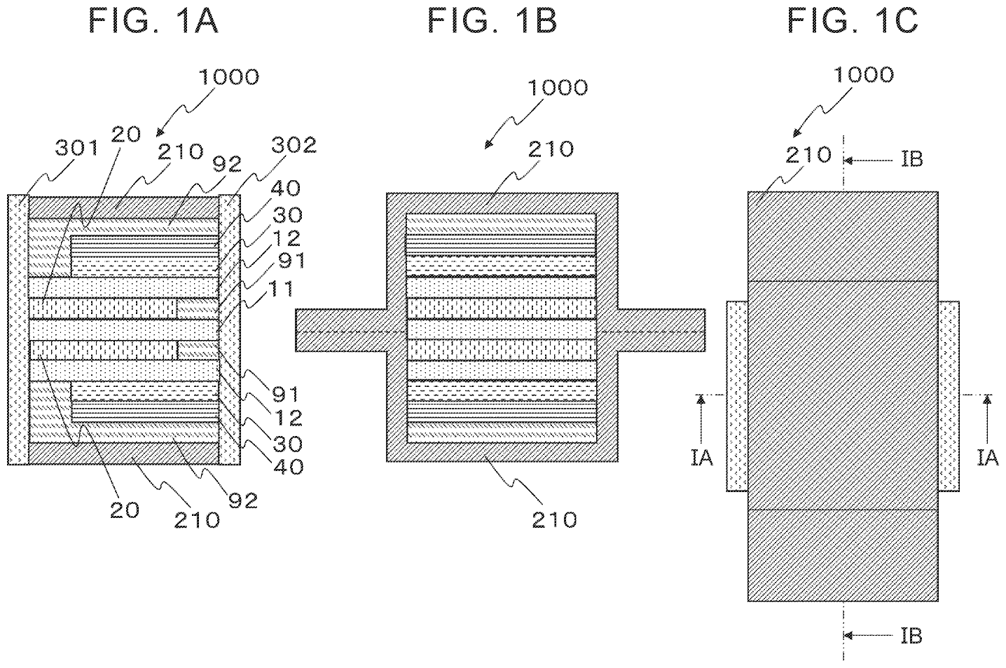

Also, for example, the monopolar battery laminate may be as shown in FIGS. 1A, 1B, and 1C. FIGS. 1A and 1B are cross-sectional views illustrating an exemplary sulfide solid-state battery according to the present disclosure. FIG. 1C is a cross-sectional view of an example of a sulfide solid-state battery according to an embodiment of the present disclosure. FIG. 1A is a cross-sectional view of a part shown in IA-IA of FIG. 1C. Further, FIG. 1B is a cross-sectional view of a part shown in IB-IB of FIG. 1C.

Specifically, in the monopolar battery laminate 110 shown in 1A, 1B, and 1C, the negative electrode active material layer 20, the solid electrolyte layer 12, the positive electrode active material layer 30, and the positive electrode current collector layer 40 are stacked in this order with the solid electrolyte layer 11 as the center. The binder-rich solid electrolyte layers 91 and 92 are arranged as protective layers at locations where electron conduction should not be performed.

Electrical contacts with the negative electrode active material layers 20 are achieved by the conductive portions 301 disposed on the left side of FIG. 1A in the sulfide solid-state battery 1000 of the present disclosure shown in FIGS. 1A, 1B, and 1C. Electrical contacts with the positive electrode current collector layers 40 are achieved by the conductive portions 302 arranged on the right side of FIG. 1A. Here, the conductive portions 301 and 302 can be obtained by applying a conductive paste to the side surface of the battery laminate 110.

In addition, in the battery 1000 of the present disclosure shown in FIGS. 1A, 1B, and 1C, portions other than the conductive portions 301 and 302 in the periphery of the battery laminate are covered with the inorganic coating layer 210. Such an inorganic coating layer can be obtained by any method. For example, by pre-forming a sheet of inorganic glass, sandwiching the battery laminate with the sheet, and heating and softening the sheet with the battery laminate, thereby coating the battery laminate with a sheet of inorganic glass, an inorganic coating layer as shown in FIGS. 1A, 1B, and 1C can be obtained.

### Bipolar Battery Laminate

When the battery laminate is a bipolar battery laminate, the two unit batteries adjacent to each other in the stacking direction may have a bipolar configuration that shares a positive electrode/negative electrode current collector layer used as both the positive electrode and the negative electrode current collector layer.

Thus, for example, the battery laminate may be a laminate of three unit batteries that share a positive/negative current collector layer used as both a positive electrode and a negative current collector layer. Specifically, the battery laminate may include a positive electrode current collector layer, a positive electrode active material layer, a solid electrolyte layer, a negative electrode active material layer, a positive electrode/negative electrode current collector layer, a positive electrode active material layer, a solid electrolyte layer, a negative electrode active material layer, a negative electrode active material layer, a positive electrode/negative electrode current collector layer, a positive electrode active material layer, a solid electrolyte layer, a negative electrode active material layer, and a negative electrode current collector layer in this order (not shown). Further, in this case, since the “positive electrode/negative electrode current collector layer” is used as both the positive electrode and the negative electrode current collector layer, it applies to both the “positive electrode current collector layer” and the “negative electrode current collector layer” in the present disclosure.

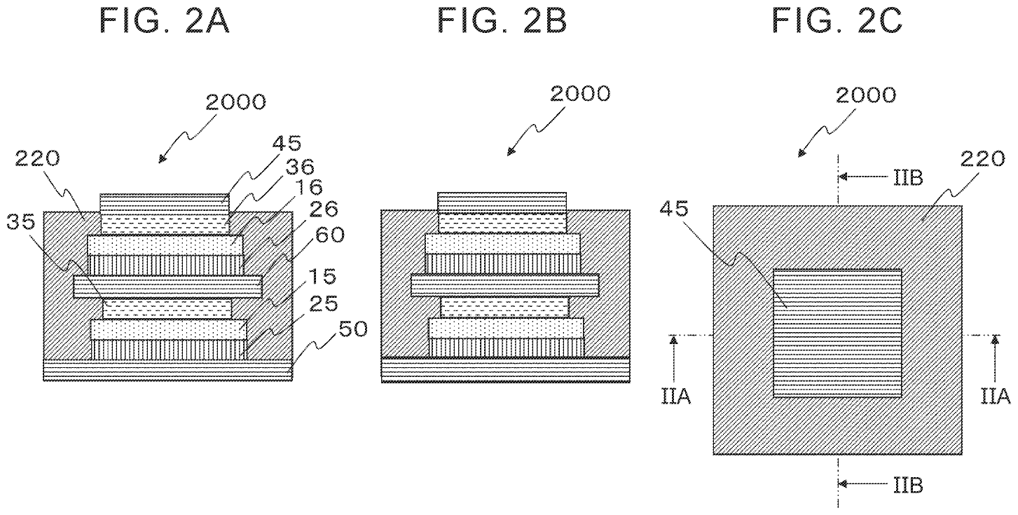

Also, for example, the bipolar battery laminate may be as shown in the FIGS. 2A, 2B, and 2C. FIG. 2A is a cross-sectional view of an example of a sulfide solid-state battery according to an embodiment of the present disclosure. FIG. 2B is a cross-sectional view illustrating an example of a sulfide solid-state battery according to an embodiment of the present disclosure. FIG. 2C is a cross-sectional view of an example of a sulfide solid-state battery according to an embodiment of the present disclosure. FIG. 2A is a cross-sectional view of a part shown in IIA-IIA of FIG. 2C. Further, FIG. 2B is a cross-sectional view of a part shown in IIB-IIB of FIG. 1C.

Specifically, in the bipolar battery laminate shown in 2A diagram, 2B diagram, and 2C, a negative electrode active material layer 25, a solid electrolyte layer 15, a positive electrode active material layer 35, a positive electrode/negative electrode current collector layer 60, a negative electrode active material layer 26, a solid electrolyte layer 16, a positive electrode active material layer 36, and an aluminum foil 45 as a positive electrode current collector layer are laminated on a roughened nickel foil 50 as a negative electrode current collector layer.

In the presently disclosed solid-state battery 2000 shown in this view 2A, 2B, and 2C, the periphery of the battery laminate is coated with an inorganic coating layer 220. Such an inorganic coating layer can be obtained by any method. For example, molten inorganic glass can be poured around a pre-molded battery laminate and cooled to cure the inorganic glass, thereby obtaining an inorganic coating layer as shown in FIGS. 2A, 2B, and 2C.

### Battery Laminate Restraint

The battery laminate of the sulfide solid-state battery of the present disclosure may be constrained in the stacking direction in use. This improves the conductivity of ions and electrons inside and between the layers of the battery laminate during charging and discharging. Then, the battery reaction can be further accelerated.

The binding force in this case is not particularly limited. The binding force may be, for example, 1.0 MPa or more, 1.5 MPa or more, 2.0 MPa or more, or 2.5 MPa or more. The upper limit of the binding force is not particularly limited. The maximum binding power may be below 50 MPa, below 30 MPa, below 10 MPa, or below 5 MPa.

Any member can be used as each member used in the battery laminate. Hereinafter, each member used in the battery laminate will be described in detail. In order to easily understand the present disclosure, each member of the battery laminate of the solid lithium ion secondary battery is described as an example. However, the sulfide solid-state battery of the present disclosure is not limited to a lithium-ion secondary battery. The sulfide solid-state battery of the present disclosure can be widely applied.

### Positive Electrode Layer

The positive electrode layer includes at least a positive electrode active material. When the unit battery is charged, lithium ions move from the positive electrode active material to the negative electrode layer via the electrolyte layer. When the battery is discharged, lithium in the negative electrode layer is ionized and returned to the positive electrode active material. The form of the positive electrode layer may be any form known as a positive electrode layer of a unit battery. For example, the positive electrode layer may include a positive electrode current collector layer and a positive electrode active material layer.

### Positive Electrode Current Collector Layer

Any of the positive electrode current collector layers generally used as the positive electrode current collector layer of the secondary battery can be adopted. Positive current collector layer may be foil-like, sheet-like, mesh-like, panting metal-like, porous-like, and foam-like. The positive electrode current collector layer may be a metal foil or a metal mesh. In particular, a metal foil has handleability and the like. The positive electrode current collector layer may be formed of a plurality of metal foils. Examples of the positive electrode current collector include Cu, Ni, Cr, Au, Pt, Ag, Al, Fe, Ti, Zn, Co, and stainless-steel.

### Positive Electrode Active Material Layer

The positive electrode active material layer includes a positive electrode active material, and may further optionally include an electrolyte, a conductive auxiliary agent, a binder, and the like. In addition, the positive electrode active material layer may contain various additives. The content of each of the positive electrode active material, the electrolyte, the conductive auxiliary agent, the binder, and the like in the positive electrode active material layer may be appropriately determined in accordance with the desired battery performance.

The positive electrode active material may be known as a positive electrode active material of a secondary battery. The positive electrode active material may be any material capable of supplying lithium to the negative electrode side during charging. For example, various lithium-containing complex oxides such as lithium cobaltate, lithium nickelate, LiNi_{1/3}Co_{1/3}Mn_{1/3}O₂, lithium manganate, and a spinel-based lithium compound can be used as the positive electrode active material. Only one positive electrode active material may be used alone, or two or more positive electrode active materials may be used in combination.

The electrolyte that may be included in the positive electrode active material layer may be a solid electrolyte, a liquid electrolyte, or a combination thereof.

As the solid electrolyte, one known as a solid electrolyte of a secondary battery may be used. The solid electrolyte may be an inorganic solid electrolyte or an organic polymer electrolyte. In particular, the inorganic solid electrolyte has ionic conductivity and heat resistance.

As the solid-solid electrolyte, for example, examples include oxide solids electrolytes such as lanthanum zirconate, LiPON, Li_{1+X}Al_{X}Ge_{2-X}(PO₄)₃, Li-SiO-based glass, Li—Al—S—O-based glass, and sulfide solids electrolytes such as Li₂S—P₂S₅, Li₂S-SiS₂, LiI-Li₂S-SiS₂, LiI-Si₂S—P₂S₅, Li₂S—P₂S₅-LiI-LiBr, LiI-Li₂S—P₂S₅, LiI-Li₂S—P₂O₅, LiI-Li₃PO₄—P₂S₅, Li₂S—P₂S₅-GeS₂. In particular, the sulfide solid electrolyte, in particular, has a high-performance sulfide solid electrolyte including at least Li, S, and P as constituent elements. The solid electrolyte may be amorphous or crystalline. The solid electrolyte may be in the form of particles, for example. Only one type of solid electrolyte may be used alone, or two or more types may be used in combination.

The electrolytic solution may contain, for example, lithium ions as carrier ions. The electrolytic solution may be, for example, a nonaqueous electrolytic solution. For example, as the electrolytic solution, a solution obtained by dissolving a lithium salt in a carbonate-based solvent at a predetermined concentration can be used. Examples of the carbonate solvent include fluoroethylene carbonate (FEC), ethylene carbonate (EC), dimethyl carbonate (DMC) and the like. Examples of the lithium salt include hexafluoride phosphate.

Examples of the conductive auxiliary agent that can be included in the positive electrode active material layers include carbon materials such as vapor-phase carbon fibers (VGCF), acetylene black (AB), Ketjen black (KB), carbon nanotubes (CNT), and carbon nanofibers (CNF); and metallic materials such as nickel, aluminum, and stainless steel. The conductive aid may be, for example, particulate or fibrous. The size is not particularly limited. Only one type of conductive aid may be used alone, or two or more types may be used in combination.

Examples of the binder that can be included in the positive electrode active material layers include a butadiene rubber (BR) based binder, a butylene rubber (IIR) based binder, an acrylate butadiene rubber (ABR) based binder, a styrene butadiene rubber (SBR) based binder, a polyvinylidene fluoride (PVdF) based binder, a polytetrafluoroethylene (PTFE) based binder, a polyimide (PT) based binder, and a polyacrylic acid based binder. Only one type of conductive aid may be used alone, or two or more types may be used in combination.

### Other

In addition to the above-described configuration, the positive electrode layer may have a general configuration as a positive electrode of a secondary battery, for example, a tab, a terminal, or the like. The positive electrode layer can be produced by applying a known method. For example, the positive electrode active material layer can be easily formed by, for example, dry or wet molding of a positive electrode mixture containing the above-described various components. The positive electrode active material layer may be formed together with the positive electrode current collector layer or may be formed separately from the positive electrode current collector layer.

### Electrolyte Layer

The electrolyte layer includes at least an electrolyte. The electrolyte layer may contain a solid electrolyte, and may optionally contain a binder or the like. In this case, the content of the solid electrolyte, the binder, and the like in the electrolyte layer is not particularly limited. In addition, the electrolyte layer may contain various additives. The electrolyte layer may include a liquid component together with the solid electrolyte. Alternatively, the electrolyte layer may include an electrolyte solution. The electrolyte layer may further include a separator or the like for holding the electrolyte solution and suppressing contact between the positive electrode and the negative electrode.

The electrolyte included in the electrolyte layer may be appropriately selected from those exemplified as the electrolyte that may be included in the positive electrode active material layer described above. The binder that may be included in the electrolyte layer may be appropriately selected from those exemplified as the binder that may be included in the positive electrode active material layer described above. The electrolyte and the binder may be used alone or in combination of two or more. The electrolyte layer can be easily formed, for example, by forming an electrolyte mixture containing the above-described electrolyte, binder, and the like by a dry method or a wet method.

On the other hand, when the electrolyte layer includes an electrolyte solution or a separator, the separator may be any separator commonly used in a secondary battery. The separator may be made of, for example, polyethylenes (PE), polypropylenes (PP), polyesters and polyamides. The separator may have a single-layer structure or a multi-layer structure. Examples of the separator having a multi-layer structure include a separator having a two-layer structure of PE-PP, a separator having a three-layer structure of PP-PE-PP or PE-PP-PE, and the like. The separator may be made of a non-woven fabric such as a cellulose non-woven fabric, a resin non-woven fabric, or a glass fiber non-woven fabric.

### Negative Electrode Layer

The negative electrode layer may include only the negative electrode current collector layer or a negative electrode active material layer and a negative electrode current collector layer. When the negative electrode layer is only the negative electrode current collector layer, lithium ions that have moved from the positive electrode during charging receive electrons and precipitate as metal lithium between the electrolyte layer and the negative electrode current collector layer. In the case where the negative electrode layer includes the negative electrode active material layer and the negative electrode current collector layer, the lithium ions transferred from the positive electrode layer during charging receive electrons and are held in the negative electrode active material of the negative electrode active material layer. When the battery is discharged, lithium in the negative electrode layer is ionized and returned to the positive electrode layer.

### Negative Electrode Active Material Layer

The negative electrode active material layer includes at least a negative electrode active material, and may optionally include an electrolyte, a conductive auxiliary agent, a binder, and the like. In addition, the negative electrode active material layer may contain various additives. The content of each of the negative electrode active material, the electrolyte, the conductive auxiliary agent, the binder, and the like in the negative electrode active material layer may be appropriately determined in accordance with the desired battery performance.

As the negative electrode active material, various materials having a potential at which lithium ions are occluded and released (charge and discharge potential) which is a lower potential than that of the positive electrode active material of the present disclosure can be employed. For example, a silicon-based active material such as Si, Si alloy, and silicon oxide; a carbon-based active material such as graphite and hard carbon; various oxide-based active materials such as lithium titanate; metallic lithium, lithium alloy, and the like can be adopted. Only one type of the negative electrode active material may be used alone, or two or more types may be used in combination.

The shape of the negative electrode active material may be any shape that is common as the negative electrode active material of the battery. For example, the negative electrode active material may be in the form of particles. The negative electrode active material particles may be primary particles or secondary particles each of which includes multiple primary particles that are aggregated.

Examples of the electrolyte that may be included in the negative electrode active material layer include the above-described solid electrolytes, electrolytic solutions, or combinations thereof. Examples of the conductive auxiliary agent that can be included in the negative electrode active material layer include the above-described carbon material and the above-described metal material. The binder that can be included in the negative electrode active material layer may be appropriately selected from those exemplified as the binder that can be included in the positive electrode active material layer described above, for example. The electrolyte and the binder may be used alone or in combination of two or more.

### Negative Electrode Current Collector Layer

The negative electrode layer may include a negative electrode current collector layer in contact with the negative electrode active material layer. Any of the negative electrode current collector layers generally used as the negative electrode current collector layer of a battery can be adopted. The negative current collector layer may be foil-like, sheet-like, mesh-like, punching metal-like, porous-like, and foam-like. The negative electrode current collector layer may be a metal foil or a metal mesh, or may be a carbon sheet. In particular, a metal foil has handleability and the like. The negative electrode current collector layer may be formed of a plurality of foils or sheets. Examples of the negative electrode current collector include Cu, Ni, Cr, Au, Pt, Ag, Al, Fe, Ti, Zn, Co, and stainless-steel. In particular, from the viewpoint of ensuring reduction resistance and from the viewpoint of difficulty in alloying with lithium, the negative electrode current collector layers may contain at least one metal selected from Cu, Ni and stainless steel.

### Examples 1 and 2

In Examples 1 and 2, the gas barrier properties were evaluated for the inorganic coating layer (Example 1) made of inorganic glass and the inorganic coating layer (Example 2) covered with the resin coating layer made of fluorine-based resin.

### Method for Producing Inorganic Coating Layer

The low glass transition point glass (57V₂O₅-23TeO₂-20P₂O₅ (mol %), glass transition point: 276° C.) and binder (acrylics) were mixed at 95:5 (wt %) and coated with a doctor blade having a coating gap of 100 micrometers on the aluminium foil. As a result, a precursor film was formed. The formed precursor film was press-baked in a uniaxial press under the following conditions. Then, the inorganic coating layer of Example 1 was prepared.

Calcination Conditions:

Single-shaft press, 10 kN, 276° C., 5 minutes
Method for Producing an Inorganic Coating Layer Coated with a Resin Coating Layer

A doctor blade with a coating gap of 50 μm was used and a coating of fluororesin was applied on the inorganic coating layer. Then, an inorganic coating layer coated with the resin coating layer of Example 2 was prepared.

### Evaluation of Gas Barrier Properties

A water vapor permeation test was performed as follows. The gas barrier properties were evaluated:
Test methods: Compliant with JISK7129-4 (differential pressure method)
Detector: Gas Chromatograph
Test gas: Water vapor (humidified atmosphere)
Temperature and humidity: 40±2° C., 90±5% (relative humidity)
Differential pressure: 1 atm

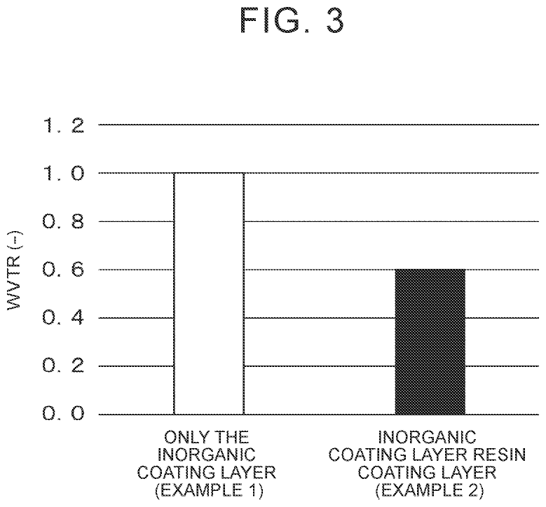

In the case of only the inorganic coating layer (Example 1) based on the water vapor transmission rate (1.0), the evaluation results are shown in FIG. 3. As is apparent from FIG. 3, the inorganic coating layer (Example 2) coated with the resin coating layer was superior in protection against water vapor permeation, that is, in gas barrier properties, as compared with the case of only the inorganic coating layer (Example 1).

### Examples 3 and 4 and Comparative Example 1

In Examples 3 and 4 and Comparative Example 1, a sulfide solid-state battery (Example 3) coated with an inorganic coating layer made of inorganic glass, a sulfide solid-state battery (Example 4) coated with a resin coating layer made of a fluorine-based resin and an inorganic coating layer, and a sulfide solid-state battery without these coating layers were subjected to a cycle test. Then, the durability was evaluated.

A sulfide solid-state battery (parallel stacked sulfide solid-state battery) was prepared as follows.

### Preparation of Positive Electrode Active Material Layer

To a polypropylene (PP) container, a polyvinylidene fluoride (PVdF)-based binder, a positive electrode active material (NCMLiNi_{1/3}Co_{1/3}Mn_{1/3}O₂), a sulfide-based solid electrolyte (Li₂S—P₂S₅-based glass ceramic), a conductive aid (vapor-grown carbon fiber), and a solvent (butyl butyrate) were added, and the mixture was stirred for 30 seconds by an ultrasonic dispersing device (UH-50 manufactured by SMT). Next, the polypropylene container was shaken with a shaker (Shibata Scientific TTM-1) for 3 minutes and further stirred with an ultrasonic disperser for 30 seconds. Then, a coating liquid for the positive electrode active material layer was obtained.

The obtained coating liquid for the positive electrode active material layer was applied on a stainless foil substrate by a blade method using an applicator, and after natural drying, dried on a hot plate at 100° C. for 30 minutes. Thus, the transfer material A having the positive electrode active material layer on one surface of the stainless foil substrate was obtained.

### Preparation of Negative Electrode Active Material Layer

A polyvinylidene fluoride (PVdF)-based binder, a negative electrode active material (lithium titanate (LTO), the sulfide-based solid electrolyte described above, and a solvent (butyl butyrate) were added to a polypropylene-made container, and the mixture was stirred for 30 seconds by an ultrasonic dispersing device (UH-50 manufactured by SMT). Then, a coating liquid for the negative electrode active material layer was obtained.

The obtained coating liquid for the negative electrode active material layer was applied on a stainless foil substrate by a blade method using an applicator, and after natural drying, dried on a hot plate at 100° C. for 30 minutes. Thus, the transfer material B having the negative electrode active material layer on one surface of the stainless foil substrate was obtained.

### Preparation of Solid Electrolyte Layer

Butyl butyrate and the sulfide-based solid electrolyte were added to a polypropylene-made container, and the mixture was stirred for 30 seconds by an ultrasonic dispersing device (UH-50 manufactured by S.M.T.). Next, the polypropylene container was shaken with a shaker (Shibata Scientific TTM-1) for 30 minutes and further stirred with an ultrasonic disperser for 30 seconds. Then, a coating liquid for the solid electrolyte layer was obtained.

The obtained coating liquid for the solid electrolyte layer was applied on a stainless foil substrate by a blade method using an applicator, and after natural drying, dried on a hot plate at 100° C. for 30 minutes. Thus, the transfer material C having the solid electrolyte layer on one surface of the stainless foil substrate was obtained.

### Preparation of a Binder-Rich Solid Electrolyte Layer

Butyl butyrate and the sulfide-based solid electrolyte were added to a polypropylene-made container, and the mixture was stirred for 30 seconds by an ultrasonic dispersing device (UH-50 manufactured by S.M.T.). Next, the polypropylene container was shaken with a shaker (Shibata Scientific TTM-1) for 30 minutes and further stirred with an ultrasonic disperser for 30 seconds. Then, a coating liquid for the binder-rich solid electrolyte layer (solid electrolyte layer having a large amount of binder) was obtained.

The obtained coating liquid for the binder-rich solid electrolyte layer was applied on a stainless foil substrate by a blade method using an applicator, and after natural drying, dried on a hot plate at 100° C. for 30 minutes. As a result, a transfer material D having a binder-rich solid electrolyte layer on one surface of the stainless foil substrate was obtained.

### Preparation of Positive Electrode Current Collector Layer

Butyl butyrate and nickel powder were added to a polypropylene container, and the mixture was stirred for 30 seconds by an ultrasonic dispersing device (UH-50 manufactured by S.M.T.). Next, the polypropylene container was shaken with a shaker (Shibata Scientific TTM-1) for 30 minutes and further stirred with an ultrasonic disperser for 30 seconds. Then, a coating liquid for the positive electrode current collector layer was obtained.

The obtained coating liquid for the positive electrode current collector layer was applied on a stainless foil substrate by a blade method using an applicator, and after natural drying, dried on a hot plate at 100° C. for 30 minutes. As a result, the transfer material E having the positive electrode current collector layer on one surface of the stainless foil substrate was obtained.

### Preparation of Sulfide Solid-State Battery Laminate

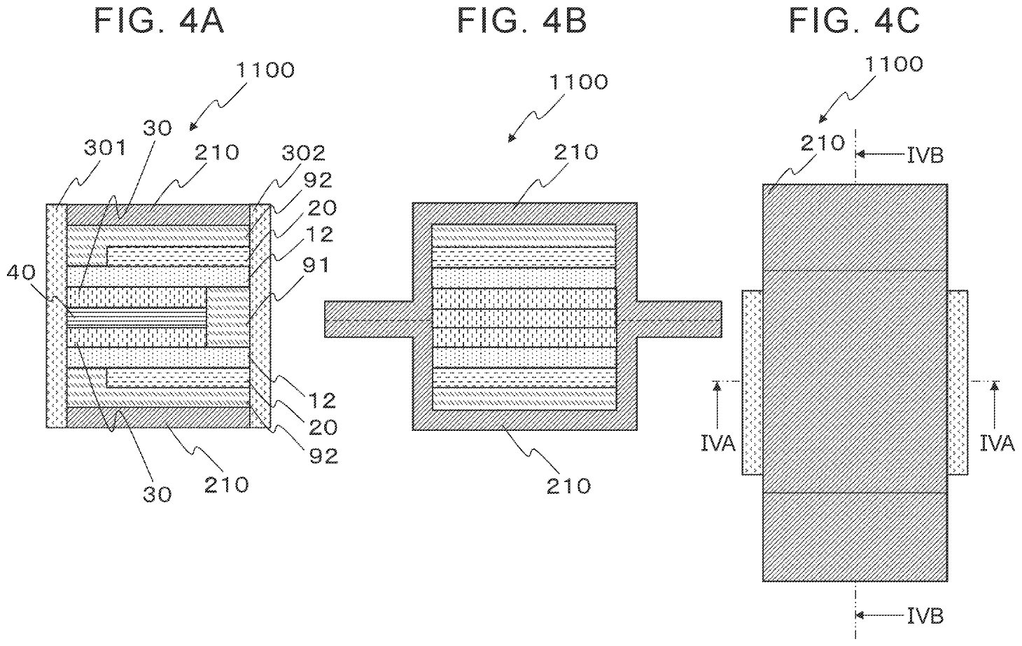

Using the transfer materials A to E obtained as described above, a sulfide solid-state battery (parallel stacked sulfide solid-state battery) as shown in FIG. 4A, FIG. 4B, and FIG. 4C was produced. The transfer of each layer was carried out under the following conditions. In addition, the frame portion of the binder-rich solid electrolyte layer was produced by coating.
Load: 10 kN
Temperature: 135° C.
Time: 10 seconds

Here, FIG. 4A is a cross-sectional view illustrating an exemplary sulfide solid-state battery. FIG. 4B is a cross-sectional view illustrating an example of a sulfide solid-state battery. FIG. 4C is a top view illustrating an example of a sulfide solid-state battery. FIG. 4A is a cross-sectional view of a part shown in IVA-IVA of FIG. 4C. Further, FIG. 4B is a cross-sectional view of a part shown in IVB-IVB of FIG. 4C.

Specifically, in the monopolar battery laminate 1100 shown in FIGS. 4A, 4B and 4C, the positive electrode active material layer 30, the solid electrolyte layer 12, and the negative electrode active material layer 20 are stacked in this order with the positive electrode current collector layer 40 as the center. The binder-rich solid electrolyte layers 91 and 92 are arranged as protective layers at locations where electron conduction should not be performed.

### Preparation of Sulfide Solid-State Battery

In the production of the battery sulfide solid-state battery of Example 3, portions of the periphery of the battery laminate other than the conductive portions 301 and 302 were covered with the inorganic coating layer 210. Here, the sheet of the inorganic coating layer was formed in advance, the battery laminate was sandwiched by the sheet, and the sheet was heated and softened by the battery laminate. The sheet of the inorganic coating layer was produced as described in Example 1.

In the production of the battery sulfide solid-state battery of Example 4, a coating of a fluorine-based resin was applied on the inorganic coating layer obtained as in Example 3 using a doctor blade having a coating gap of 50 μm. Then, the inorganic coating layer was coated with a resin coating layer.

On the other hand, in the preparation of the sulfide solid-state battery of Comparative Example 1, neither the inorganic coating layer nor the resin coating layer was provided.

Thereafter, in the preparation of the sulfide solid-state battery of Examples 3 and 4 and Comparative Example 1, a conductive portion is provided in the sulfide solid-state battery laminate. Specifically, electric contacts with the negative electrode active material layers 20 were achieved by the conductive portions 301 disposed on the left side of FIG. 4A, as shown in FIGS. 4A, 4B, and 4C. In addition, electric contacts with the positive electrode current collector layers 40 were achieved by the conductive portions 302 disposed on the right side of FIG. 4A. Here, the conductive portions 301 and 302 were obtained by applying a conductive paste to the side surface of the battery laminate 110.

### Cycle Characterization of Battery

Cycle evaluations were measured for the sulfide solid-state batteries of Examples 3 and 4 and Comparative Example 1 obtained above. The measurements were carried out at 25° C. and 0.33C constant-current constant-voltage charging and discharging within 1.5 to 3.0V.

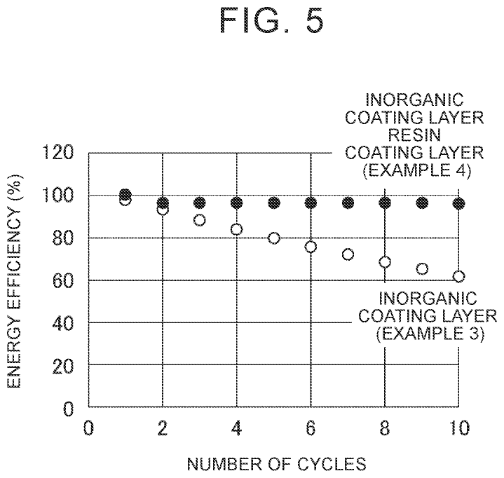

FIG. 5 shows a change in charge/discharge efficiency with an increase in the number of cycles in which the charge/discharge efficiency in the first cycle is set to 100%. In the sulfide solid-state battery of Comparative Example 1 in which neither the inorganic coating layer nor the resin coating layer was provided, the charge-discharge cycle could not be performed.

On the other hand, as shown in FIG. 5, in the sulfide solid-state battery of Example 3 in which the inorganic coating layer was provided, and in the sulfide solid-state battery of Example 4 in which both the inorganic coating layer and the resin coating layer were provided, charge and discharge cycles could be performed up to at least 10 cycles. Further, when the sulfide solid-state battery of Example 3 and the sulfide solid-state battery of Example 4 were compared, the sulfide solid-state battery of Example 4, which provided both the inorganic coating layer and the resin coating layer, had better cycle characteristics than the sulfide solid-state battery of Example 3, which provided the inorganic coating layer.

### Evaluation of Solderability of Batteries

The sulfide solid-state batteries of Examples 3 and 4 were reflow soldered to a printed circuit board using lead-free solder (glass transition point about 220° C.) in a reflow furnace at a soldering temperature of about 250° C. After the solder was cooled and cured, it was confirmed that the sulfide solid-state batteries of Examples 3 and 4 could be charged and discharged while being fixed to the printed circuit board.

What is claimed is:

1. A sulfide solid-state battery comprising:
a battery laminate including one or more unit batteries, the unit battery configured of a positive electrode layer, a solid electrolyte layer, and a negative electrode layer laminated in this order; and
an inorganic coating layer coating at least a portion of a periphery of the battery laminate, wherein
at least one of the positive electrode layer, the solid electrolyte layer, and the negative electrode layer contains a sulfide solid electrolyte, and
the inorganic coating layer is made of an inorganic glass of which a glass transition point is 260° C. or higher and 360° C. or lower.

2. The sulfide solid-state battery according to claim 1, wherein the inorganic coating layer is coated with a resin coating layer made of a fluorine-based resin.

3. A printed circuit board with a sulfide solid-state battery, comprising:
a printed circuit board; and
the sulfide solid-state battery according to claim 1, the sulfide solid-state battery being soldered to the printed circuit board.

4. A manufacturing method of the printed circuit board with the sulfide solid-state battery according to claim 3, the manufacturing method comprising soldering the sulfide solid-state battery to the printed circuit board by reflow soldering.

5. A manufacturing method of the sulfide solid-state battery according to claim 1, the manufacturing method comprising:
(a) preparing the battery laminate; and
(b) forming the inorganic coating layer on at least a portion of the periphery of the battery laminate.
